(19) United States
(12) Patent Application Publication
(10) Pub. No.: US 2026/0085383 A1
(43) Pub. Date: Mar. 26, 2026

(54) ALLOY MATERIAL FOR PROBE PINS

(71) Applicants: ISHIFUKU METAL INDUSTRY CO., LTD., Tokyo (JP); YOKOWO CO., LTD., Tokyo (JP)

(72) Inventors: Koichi HASEGAWA, Soka-shi (JP); Yasunori EGAWA, Soka-shi (JP); Atsuo MATSUZAWA, Soka-shi (JP); Kenichi SATO, Tomioka-shi (JP)

(73) Assignees: ISHIFUKU METAL INDUSTRY CO., LTD., Tokyo (JP); YOKOWO CO., LTD., Tokyo (JP)

(21) Appl. No.: 19/109,069

(22) PCT Filed: Aug. 31, 2023
(86) PCT No.: PCT/JP2023/031796

§ 371 Date: Mar. 5, 2025

(30) Foreign Application Priority Data
Sep. 7, 2022 (JP) 2022-141820

(51) Int. Cl. C22C 5/04

(52) U.S. Cl. CPC C22C 5/04

(57) ABSTRACT

An object of the present invention is to provide an alloy material for probe pins that can suppress the diffusion of components between solder in the circuit connecting portion of an inspection target and a probe material during probe inspection. The alloy material for probe pins of the present invention consists of: 40 mass % or more and 95 mass % or less of Pt; 0.5 mass % or more and 50 mass % or less of Cu; and 3 mass % or more and 50 mass % or less of Ni.

### TECHNICAL FIELD

The present invention relates to an alloy material for manufacturing probe pins (hereinafter referred to as “probe material”) for inspecting the electrical characteristics of an integrated circuit on a semiconductor wafer, a liquid crystal display device, or the like.

### BACKGROUND ART

In the inspection of the electrical characteristics of an integrated circuit formed on a semiconductor wafer, a liquid crystal display device, or the like, a socket or a probe card in which a plurality of probes are incorporated has been used. This inspection is performed by bringing probe pins incorporated in the socket or the probe card into contact with an electrode, a terminal, or a conductive portion of the integrated circuit, the liquid crystal display device, or the like.

Such probe pins are required to have low contact resistance and hardness enough to withstand repeated contact. For example, a beryllium-copper alloy, tungsten, a tungsten alloy, a platinum alloy, or a palladium alloy is used as a probe material.

In U.S. Pat. No. 1,935,897 A, there is a disclosure of a palladium alloy (hereinafter referred to as “AgPdCu alloy”) composed of not less than 16% and not more than 50% copper, palladium ranging from about 35% to about 59%, and silver to the extent of not less than 4%.

### CITATION LIST

### Patent Literature

[PTL 1]U.S. Pat. No. 1,935,897 A

### SUMMARY OF INVENTION

### Technical Problem

The AgPdCu alloy, which has excellent plastic workability and is precipitation-hardened, has hitherto been used as the probe material because of its shape stability resulting from its hardness and its low specific resistance characteristic. However, the following problem has been found when such probe material is used in a circuit connecting portion where solder (e.g., Sn—Bi-based solder) is used. Specifically, during inspection, a probe pin and the solder are repeatedly brought into contact with each other, and an electrical current flows therebetween. As a result, a solder component such as Sn and a component of the probe material interdiffuse owing to the resulting Joule heat or the like, and a tip end of the probe pin tends to be rapidly consumed. In such a case, contact resistance fluctuates suddenly or over time, and the fluctuation causes an inspection defect. Accordingly, cleaning or exchange of a tip end portion of the probe pin to be brought into contact is required, and there has been a problem in that the operating rate of an inspection step is reduced.

In view of the foregoing, there is a strong demand for the development of a probe material having solder resistance sufficient to suppress the diffusion of the solder component.

An object of the present invention is to provide a probe material that can suppress the diffusion of components between solder in the circuit connecting portion of an inspection target and the probe material during probe inspection.

### Solution to Problem

The inventors of the present invention have found a probe material consisting of: 40 mass % or more and 95 mass % or less of Pt; 0.5 mass % or more and 50 mass % or less of Cu; and 3 mass % or more and 50 mass % or less of Ni. Thus, the inventors have completed the present invention.

### Advantageous Effects of Invention

According to the present invention, it is possible to provide a probe material that meets both the hardness and the specific resistance required for a probe material. This probe material suppresses the diffusion of components between the solder in the circuit connecting portion of the inspection target and the probe material during inspection.

### DESCRIPTION OF EMBODIMENTS

The present invention is directed to a probe material consisting of: 40 mass % or more and 95 mass % or less of Pt; 0.5 mass % or more and 50 mass % or less of Cu; and 3 mass % or more and 50 mass % or less of Ni.

Although Pt has excellent corrosion resistance, when its content is less than 40 mass %, the corrosion resistance of the probe material becomes insufficient. Meanwhile, when the content is more than 95 mass %, even after work hardening through strong working, the hardness of the probe material does not reach 300 HV, and thus fails to achieve the hardness required for a probe pin.

As another aspect, the content of Pt may be 45 mass % or more and 90 mass % or less. In addition, as a further aspect, the content of Pt may be 50 mass % or more and 83 mass % or less.

In contrast to Pt, Cu can improve the hardness of the probe material while maintaining satisfactory workability. However, when the content of Cu is less than 0.5 mass %, the hardness of the probe material becomes insufficient. Meanwhile, when the content of Cu is more than 50 mass %, the corrosion resistance of the probe material is reduced. As another aspect, the content of Cu may be 9 mass % or more.

Ni can improve the hardness of the probe material without reducing its solder resistance.

However, when the content of Ni is less than 3 mass %, the degree of hardness improvement achieved by working is insufficient. Meanwhile, when the content of Ni is more than 50 mass %, it becomes difficult to perform plastic working, such as cold rolling or wire drawing.

As another aspect, the content of Ni may be 5 mass % or more and 40 mass % or less. In addition, as a further aspect, the content of Ni may be 10 mass % or more and 35 mass % or less.

It is important for the alloy material of the present invention to suppress a phenomenon in which a tip end of a probe pin is consumed through diffusion of components between the solder and the probe material. While the alloy material of the present invention is not required to have hardness as high as that of an existing AgPdCu alloy, sufficient hardness is desirable to prevent its contact surface from being mechanically crushed as the number of inspections increases. Although the alloy material can be used as long as its hardness is 200 HV or more, a hardness of 250 HV or more is desirable, and a hardness of 300 HV or more is preferred.

The hardness may be improved by work hardening.

In addition, apart from hardness, suppression of the specific resistance of the alloy material is required, because the generation of Joule heat by an electric current flowing during inspection is undesirable. Although the alloy material can be basically used as long as its specific resistance is 90 μΩ·cm or less, a lower specific resistance is desired.

The mechanism by which diffusion of components between the solder and the probe material is suppressed in the alloy material of the present invention is presumed as described below. Specifically, it is conceived that Ni included in the probe material forms a thin and dense intermetallic compound layer (e.g., Sn—Ni) at the interface where the solder and the probe pin are brought into contact with each other. This intermetallic compound layer exhibits a suppressing effect on the diffusion of the components between the solder and the probe material, and thus prevents the tip end of the probe pin from being easily consumed.

### EXAMPLES

Examples of the present invention are described.

First, Pt, Cu, and Ni were mixed so as to achieve the compositions shown in Table 1. The mixture was then melted in an argon atmosphere by an arc melting method to produce alloy ingots. The compositions and respective characteristics of alloys of Examples and Comparative Examples are shown in Table 1.

Each of the produced alloy ingots was repeatedly subjected to rolling and heat treatment to produce a sheet material having a reduction ratio [=((thickness before rolling-thickness after rolling)/thickness before rolling)×100] of 80%, and the produced sheet material was used as a test piece for evaluating hardness and solder resistance.

During the production of the sheet material, an evaluation of workability was conducted as follows: alloy compositions capable of producing a sheet material with a reduction ratio of 80% were indicated with the symbol “o”; conversely, any alloy composition that failed to achieve this reduction ratio was indicated with the symbol “x”. The alloy composition that could not produce a sheet material with a reduction ratio of 80% and was rated “x” for its workability (specifically Comparative Example 2) was not subjected to subsequent tests.

The produced test pieces of the alloys were each subjected to the following evaluations. The results are shown in Table 2.

The hardness at the center of the cross-section of the test piece was measured with a micro Vickers hardness tester under the conditions of a load of 200 gf and a holding time of 10 seconds. The hardness measured under these conditions is referred to as “worked material hardness.”

The solder resistance was evaluated as described below. Sn—Bi-based solder was applied onto the test piece (with the size of 10 mm×10 mm×0.5 mm in thickness), and the solder on the test piece was melted through heat treatment in an N₂ atmosphere under the conditions of 250° C. and 1 hour. After the heat treatment, the test piece was embedded in a resin, and then its cross-section was exposed. An interface between the solder and the test piece was subjected to line analysis in a vertical direction with an EPMA. Based on the line analysis results of Sn (a component for the solder) and the main element of the alloy (Pt in Examples or Pd in Comparative Example 1), the layer in which Sn and the main element coexisted was regarded as a diffusion layer, and its thickness was measured.

It was evaluated that the smaller the thickness of the measured diffusion layer, the higher the solder resistance. Specifically, alloys were evaluated as follows: an alloy forming a diffusion layer having a thickness of less than 100 μm was indicated with the symbol “oo”; an alloy forming a diffusion layer having a thickness of from 100 μm to 200 μm was indicated with the symbol “o”; and an alloy forming a diffusion layer having a thickness of 200 μm or more was indicated with the symbol “x”. The evaluation results are shown in Table 2.

The specific resistance was evaluated as described below. A sheet material processed so as to have a reduction ratio [=((thickness before rolling−thickness after rolling)/thickness before rolling)×100] of 90% was used as a test piece for evaluating the specific resistance. The specific resistance was calculated based on the electrical resistance of each sample measured at room temperature, in accordance with Equation 1.

$$Equation 1$$

$$specific resistance = ( electrical resistance \times cross - sectional area ) / measurement length$$

TABLE 1

| No. | Composition (mass %) | Workability |
|---|---|---|
| Example 1 | 95Pt2Cu3Ni | ∘ |
| Example 2 | 90Pt0.5Cu9.5Ni | ∘ |
| Example 3 | 90Pt5Cu5Ni | ∘ |
| Example 4 | 80Pt15Cu5Ni | ∘ |
| Example 5 | 80Pt10Cu10Ni | ∘ |
| Example 6 | 70Pt25Cu5Ni | ∘ |
| Example 7 | 70Pt10Cu20Ni | ∘ |
| Example 8 | 60Pt30Cu10Ni | ∘ |
| Example 9 | 60Pt20Cu20Ni | ∘ |
| Example 10 | 60Pt10Cu30Ni | ∘ |
| Example 11 | 50Pt40Cu10Ni | ∘ |
| Example 12 | 50Pt30Cu20Ni | ∘ |
| Example 13 | 50Pt10Cu40Ni | ∘ |
| Example 14 | 40Pt40Cu20Ni | ∘ |
| Comparative Example 1 | 24.5Ag45Pd25Cu0.5In | ∘ |
| Comparative Example 2 | 37Pt3Cu60Ni | x |

TABLE 2

| | | Worked | Thickness of | Evaluation of |
|---|---|---|---|---|
| | Specific | material | diffusion | thickness of |
| | resistance | hardness | layer | diffusion |
| No. | μ Ω · cm | HV | μm | layer |
| Example 1 | 31 | 300 | 30 | ∘∘ |
| Example 2 | 32 | 385 | 40 | ∘∘ |
| Example 3 | 48 | 360 | 40 | ∘∘ |
| Example 4 | 67 | 370 | 40 | ∘∘ |
| Example 5 | 58 | 400 | 20 | ∘∘ |
| Example 6 | 79 | 360 | 15 | ∘∘ |
| Example 7 | 49 | 425 | 20 | ∘∘ |
| Example 8 | 60 | 390 | 20 | ∘∘ |
| Example 9 | 66 | 435 | 20 | ∘∘ |
| Example 10 | 52 | 430 | 25 | ∘∘ |
| Example 11 | 60 | 350 | 35 | ∘∘ |
| Example 12 | 66 | 425 | 30 | ∘∘ |
| Example 13 | 53 | 420 | 35 | ∘∘ |
| Example 14 | 58 | 340 | 30 | ∘∘ |
| Comparative | 25 | 350 | 600 or more | x |
| Example 1 | | | | |

As can be seen from the above-mentioned results, in each of Examples 1 to 14, a hardness of 300 HV or more and a specific resistance of less than 90 μΩ·cm are achieved through 80% rolling, while high solder resistance is obtained.

It is found from the above-mentioned results that the alloys produced according to the present invention each have high solder resistance, and also have the hardness and the specific resistance that a probe material is required to have. Consequently, according to the present invention, an alloy material suitable for manufacturing probe pins having high solder resistance can be provided.

1. An alloy material for probe pins, consisting of:
40 mass % or more and 95 mass % or less of Pt;
0.5 mass % or more and 50 mass % or less of Cu; and
3 mass % or more and 50 mass % or less of Ni.
